(19) United States
(12) Patent Application Publication
(10) Pub. No.: US 2012/0024232 A1
(43) Pub. Date: Feb. 2, 2012

(54) EVAPORATION SOURCE FOR ORGANIC MATERIAL AND VAPOR DEPOSITING APPARATUS INCLUDING THE SAME

(75) Inventors: Choong-Ho Lee, Yongin-City (KR); Da-Hee Jeong, Yongin-City (KR); Yoon-Chan Oh, Yongin-City (KR)

(73) Assignee: SAMSUNG MOBILE DISPLAY CO., LTD., Yongin-City (KR)

(21) Appl. No.: 13/190,778

(22) Filed: Jul. 26, 2011

(30) Foreign Application Priority Data
Jul. 29, 2010 (KR) 10-2010-0073530

(51) Int. Cl. C23C 16/448

(52) U.S. Cl. 118/726

(57) ABSTRACT

The present invention described technology relates generally to an organic material evaporation source that can deposit an organic material on a large-sized substrate, and a vapor deposition apparatus including the same. An organic material evaporation source according to an exemplary embodiment of the present invention includes a crucible including a body and nozzle connected to an opening formed at one side of the body; a heater disposed adjacent to the crucible; and a housing receiving the crucible and the heater, and the crucible is formed of a metal coated with steel use stainless (SUS).

### CLAIM OF PRIORITY

This application makes reference to, incorporates the same herein, and claims all benefits accruing under 35 U.S.C. §119 from an application earlier filed in the Korean Intellectual Property Office on 29 Jul. 2010 and there duly assigned Serial No. 10-2010-0073530.

### BACKGROUND OF THE INVENTION

1. Field of the Invention

The present invention described technology relates generally to an organic material evaporation source and a vapor depositing apparatus including the same. More particularly, the present invention described technology relates generally to an organic material evaporation source that can deposit an organic material to a large-sized substrate, and a depositing apparatus including the same.

2. Description of the Related Art

An organic light emitting diode (OLED) display is a flat display device that has a self emissive characteristic and does not require a separate light source so that it can be made light weight and thin. Particularly, the OLED display exhibits quality characteristics such as low power consumption, high luminance, high response speed, and as such, the OLED display receives much attention as a next-generation display device.

In general, the OLED display includes an organic light emitting element that includes an anode, an organic emission layer, and a cathode. Holes and electrons are injected from the anode and the cathode, respectively, to form excitons, and the excitons make a transition to a ground state, thereby causing the organic light emitting diode to emit light.

The organic emission layer is formed with an organic thin film, and the organic thin film is formed on a substrate of the OLED display, using a physical vapor deposition (PVD) method like a vacuum evaporation method and a wet coating method. As a general method to form a metal electrode and an organic thin film, the vacuum evaporation method is used to form an organic thin film in a vapor deposition apparatus that includes an organic material evaporation source having a crucible by inserting a vapor deposition material in the crucible and depositing the vapor deposition material by heating the crucible with a predetermined temperature.

In order to deposit an organic thin film on a large-sized substrate using the evaporation apparatus, the organic material evaporation source and the crucible provided therein should be made large. As the crucible is increased in size, internal temperature deviation of the crucible may be increased, and the organic material, which is a vapor deposition material, may be differentially exhausted according to a location of the crucible so that efficiency of the organic thin film may deteriorate. In addition, when a difference between the temperature applied to the organic material and a sublimation temperature is greater than a predetermined temperature, the organic material may be degenerated, and the temperature deviation in the crucible makes control of the temperature applied to the organic material difficult, and accordingly, the degeneration of the organic material cannot be effectively suppressed.

In addition, a method for increasing efficiency of the organic material even though the temperature deviation occurs by forming the internal structure of the crucible complicated has been suggested, but the organic material is evaporated or sublimated when the internal structure of the crucible is complicated so that the internal pressure of the crucible is increased and the evaporation temperature or the sublimation temperature of the organic material is increased, and accordingly a temperature-sensitive organic material may be degenerated.

The above information disclosed in this Background section is only for enhancement of understanding of the background of the described technology and therefore it may contain information that does not form the prior art that is already known in this country to a person of ordinary skill in the art.

### SUMMARY OF THE INVENTION

The described technology has been made in an effort to provide an organic material evaporation source that can reduce internal temperature deviation while forming a large-sized crucible and prevent generation of foreign particles during a vapor deposition process.

Further, the present invention is provided to suppress deformation of internal parts of the organic material evaporation source due to thermal expansion differences therebetween.

Another purpose of the present invention is to provide an organic material vapor deposition apparatus that can form an organic thin film with a uniform thickness on a large-sized substrate.

An organic material evaporation source according to an exemplary embodiment of the present invention includes a crucible including a body and nozzle connected to an opening formed at one side of the body, a heater disposed adjacent to the crucible, and a housing receiving the crucible and the heater. The crucible is formed of a metal coated with steel use stainless (SUS).

The metal may be copper or aluminum.

The thickness of the SUS formed on the metal may be about 0.05 mm to about 0.5 mm.

The organic metal evaporation source according to the exemplary embodiment of the present invention may further include a heater frame disposed between the crucible and the housing and a support supporting the crucible and the heater frame. The heater frame supports the heater. The support may include a first support that connects the crucible to the heater frame and a second support that connects the heater frame to the housing.

The first support may include a first center support connected to a center portion of the crucible and the heater frame and a first edge support connected to an edge of the crucible and the heater frame. The first center support may be formed to be fixed to the crucible and the heater frame, and the first edge support may be formed to be movable between the crucible and the heater frame.

The second support may include a second center support connected to a center portion of the heater frame and the housing and a second edge support connected to an edge of the heater frame and the housing. The second center support may be formed to be fixed to the heater frame and the housing, and the second edge support may be formed to be movable between the heater frame and the housing.

A first groove may be formed in at least one of the crucible and the heater frame, connected with the first center support and a first end of the first center support may be inserted to the first groove. Further, a second groove may be formed in at least one of the heater frame and the housing, connected with the second center support and a first end of the second center support may be inserted to the second groove.

The first edge support and the second edge support may have a sphere or cylinder shape.

The support may include ceramic or glass.

The organic material evaporation source according to the exemplary embodiment of the present invention may further include an insulating plate formed between the heater frame and the housing.

The housing may include a cooling member.

The nozzles may be arranged with a constant distance from each other along one side of the crucible.

An organic metal vapor deposition apparatus according to another exemplary embodiment of the present invention includes a substrate fixing member for fixing a substrate, an organic material evaporation source for depositing an organic material on the substrate, an evaporation source support member for supporting the organic material evaporation source, and a chamber receiving the substrate, the substrate fixing member, the organic material evaporation source, and the evaporation source support member. The organic material evaporation source includes a crucible including a body and nozzles connected to an opening formed at one side of the body, a heater disposed adjacent to the crucible, and a housing receiving the crucible and the heater, and the crucible is formed of a metal coated with steel use stainless (SUS).

The metal may be copper or aluminum.

The nozzles may be arranged with a constant distance from each other along a first direction at one side of the organic material evaporation source, facing the substrate of the crucible.

The organic material vapor deposition apparatus according to the other exemplary embodiment may further include a blocking plate disposed between the substrate and the organic material evaporation source.

The blocking plate may be extended along the first direction, and is disposed adjacent to one side of the organic material evaporation source when viewed from the substrate to the organic material evaporation source. A width of the blocking plate, measured along a second direction that is perpendicular to the first direction may have a portion corresponding to the center of the organic material evaporation source formed to be greater than a portion corresponding to an edge of the organic material evaporation source.

The blocking plate may be formed as a pair that are symmetric with reference to the organic material evaporation source.

The evaporation support member may include a guide for transferring the organic material evaporation source along a second direction that crosses the first direction and the blocking plate is transferred with a speed that is the same as the transfer speed of the organic material evaporation source.

According to the exemplary embodiments of the present invention, internal temperature deviation and internal pressure deviation that may occur during vapor deposition of the organic material on the large-sized substrate can be suppressed, thereby suppressing degeneration of the organic material, and generation of foreign particles during the vapor deposition process can be suppressed.

In addition, deformation and scratch due to thermal expansion difference between each part of the organic material evaporation source can be suppressed.

Further, the organic material can be uniformly exhausted and an organic thin film can be formed on the large-sized substrate with a uniform thickness.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a perspective view of an organic material evaporation source according to an exemplary present invention.

FIG. 2 is a side cross-sectional view of the organic material evaporation source according to the exemplary embodiment of the present invention, taken along the line II-II of FIG. 1.

FIG. 3 is a front view of the organic material evaporation source according to the exemplary embodiment of the present invention.

FIGS. 4A to 4C are cross-sectional views of a center support of the organic material evaporation source according to the exemplary embodiment and exemplary variations of the present invention.

FIGS. 5A and 5B are cross-sectional views of an edge support of the organic material evaporation source according to the exemplary embodiment and exemplary variations of the present invention.

FIG. 6 is a cross-sectional view of a crucible of an organic material evaporation source according to the exemplary embodiment of the present invention, taken along the line VI-VI of FIG. 3.

FIG. 7 is a schematic cross-sectional view of an organic material vapor deposition apparatus according to an exemplary embodiment of the present invention.

FIG. 8 is a schematic front view of an evaporation source of the organic material vapor deposition apparatus according to the exemplary embodiment of the present invention.

### DETAILED DESCRIPTION OF THE INVENTION

The present invention will be described more fully hereinafter with reference to the accompanying drawings, in which exemplary embodiments of the invention are shown.

The drawings and description are to be regarded as illustrative in nature and not restrictive. Like reference numerals designate like elements throughout the specification. The size and thickness of each component shown in the drawings are arbitrarily shown for understanding and ease of description, but the present invention is not limited thereto.

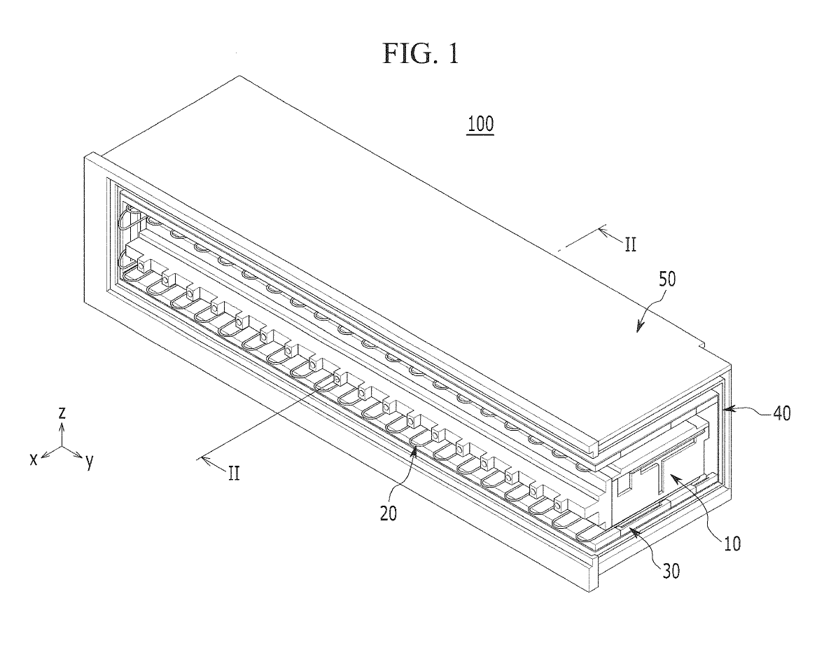

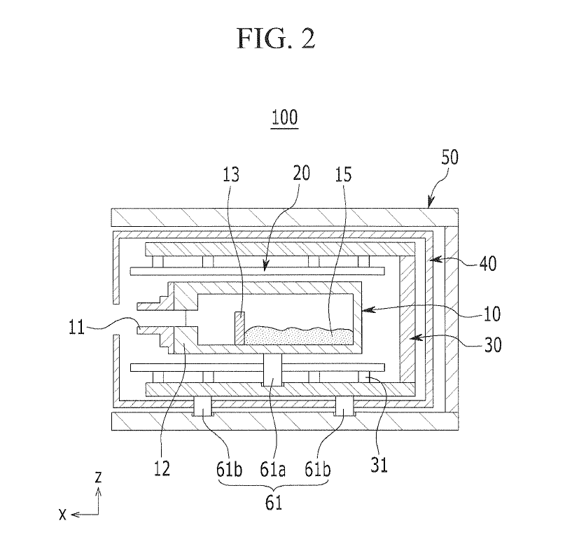

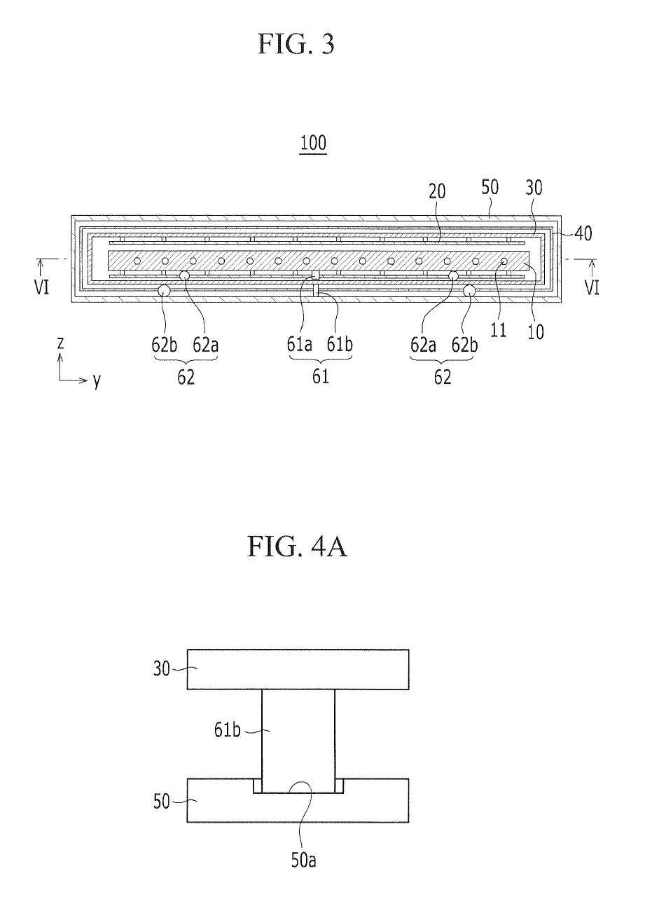

FIG. 1 is a perspective view of an organic material evaporation source according to an exemplary embodiment of the present invention, FIG. 2 is a side cross-sectional view of the organic material evaporation source according to the exemplary embodiment of the present invention, taken along the line II-II of FIG. 1, and FIG. 3 is a front view of the organic material evaporation source according to the exemplary embodiment of the present invention.

Referring to FIGS. 1 to 3, an organic material evaporation source 100 according to the present exemplary embodiment includes a crucible 10, a heater 20, and a housing 50 that receives the crucible 10 and the heater 20. The organic material evaporation source 100 may further include a heater frame 30 that arranges the heater 20 to be adjacent to the crucible 10 and fixes the same, and an insulating plate 40 disposed between the heater frame 30 and the housing 50. In FIG. 1, one side of the housing 50 and a front side of the insulating plate 40 are omitted, and in FIG. 3, the front side of the insulating plate 40 is omitted for better understanding and ease of description.

According to the present exemplary embodiment, the crucible 10 includes a body 12 and a barrier rib 13 formed in the body 12. An organic material 15 is stored in one space partitioned by the barrier rib 13 in the body 12 of the crucible 10, and the organic material 15 is evaporated or sublimated by being heated by the heater 20 disposed the outside of the crucible 10 and then emitted to the outside. In the body 12 of the crucible 10, an opening is formed at an opposite side of the space where the organic material 15 is stored in the crucible 10. In addition, the crucible 10 includes a nozzle 11 formed at a side of the body 12 and communicating with the opening formed at one side of the body 12, and the evaporated or sublimated organic material is sprayed to the substrate through the nozzle 11 such that an organic thin film is formed.

The heater 20 is disposed at the outside of the crucible 10. In the present exemplary embodiment, the heater 20 may be provided at upper and lower portions of the crucible 10 with reference to the z-axis, but it may be formed at only one side or formed to surround the entire sides of the crucible 10, excluding the side where the nozzle 11 is formed. That is, the arrangement and the shape of the heater 20 may be variously modified as long as the heater 20 can heat the organic material 15 received in the crucible 10 to the evaporation temperature or the sublimation temperature.

The crucible 10 is formed with a material having excellent thermal conductivity in order to effectively transfer the heat generated from the heater 20 to the organic material 15 and minimize the temperature deviation in the crucible 10. In the present exemplary embodiment, a metal such as cooper or aluminum may be used as the material having excellent thermal conductivity.

However, the strength of the material having excellent thermal conductivity is not strong enough so that it may be easily broken. In addition, when the material is heated to a temperature that is as high as about 400° C. to about 600° C. under high vacuum state, metal atoms such as cooper atoms or aluminum atoms may be partially sublimated so that the substrate where the organic material is deposited may be contaminated.

Stainless steel has high strength at high temperature with high vacuum condition, and thus when the crucible 10 is formed with stainless steel, the crucible 10 is not easily broken during the vapor deposition process and sublimation does not occur at high temperature so that foreign particles can be prevented from being generated. However, the stainless steel has low thermal conductivity so that the heat generated from the heater 20 cannot be effectively transferred to the organic material 15, and an internal temperature deviation of the crucible 10 may be high.

Accordingly, in the present exemplary embodiment, the crucible 10 is formed by coating steel use stainless (SUS) to a metal such as copper or aluminum. Particularly, since copper and partial aluminum have a thermal expansion coefficient that is almost the same as that of SUS, even though the metal is coated with SUS, no breakage may occur due to the thermal expansion amount difference at a contact side of the metal and the SUS when the temperature of the crucible 10 is increased.

The coating of the SUS may be performed through brazing in the vacuum state, and the metal can completely adhere to the SUS through the brazing. The brazing is a method to deposit material by disposing an alloy having a low melting point between the materials and heating to a temperature at which the alloy can be melt, and in the present exemplary embodiment, a metal such as cooper or aluminum adheres to the SUS using high-frequency heat under the vacuum state.

The SUS coated to the metal and the like has a thickness of about 0.05 mm to about 0.5 mm. In order to assure the solidity of the crucible 10 and suppress generation of the foreign particles, the SUS is preferably coated with a thickness of greater than about 0.05 mm, and, in consideration of the lower thermal conductivity of the SUS, the thickness of the crucible 10 is preferably less than about 0.5 mm to increase the thermal conductivity efficiency through the crucible 10 and suppress the internal temperature deviation of the crucible 10.

As described, the crucible 10 is formed with the metal coated with the SUS so that the terminal conductivity of the crucible 10 can be increased and the internal temperature deviation of the crucible 10 can be suppressed. Accordingly, the organic material 15 can be uniformly exhausted, degeneration of the organic material 15 can be suppressed and simultaneously the generation of the foreign particles during the evaporation process can be suppressed, thereby preventing contamination of the substrate. Further, the solidity of the crucible 10 is assured so that the crucible 10 can be prevented from being broken during the evaporation process. In the present exemplary embodiment, the organic material evaporation source 100 is exemplarily formed as a linear evaporation source, but the present invention is not limited thereto. That is, the shape of the evaporation source applied to the present invention can be variously modified according to the purpose of the present invention.

The organic material evaporation source 100 according to the present exemplary embodiment further includes the heater frame 30 for fixing the heater 20. The heater frame 30 fixes the heater 20 using a heater support 31, is connected with the crucible 10 through first supports 61a and 62a, and connected with the housing 50 through second supports 61b and 62b. The heater 20 can be fixed to a consistent position and the crucible 10 and the heater 20 can be fixed to a consistent position in the housing by the heater frame 30 and the supports 61 and 62. Thus, the organic material 15 can be uniformly heated, and the evaporated or sublimated organic material can be deposited to a consistent position of the substrate in the case that the organic material evaporation source 100 is transferred during the vapor deposition process.

Meanwhile, during a process that the heat generated from the heater 20 is transferred to the crucible 10, large thermal energy may be transferred through the supports 61 and 62 due to a high temperature deviation between the crucible 10, the heater frame 30, and the housing 50. As described, when the heat is transferred through the supports 61 and 62, the temperature deviation of the crucible 10 may occur so that the organic material may be differently exhausted or degenerated. Further, the temperature deviation at a contact points in the upper or lower portion of the supports 61 and 62 is very high so that the supports 61 and 62 may be damaged due to heat and impact.

Thus, the supports 61 and 62 according to the present exemplary embodiment are formed with ceramic or glass having very low thermal conductivity. In this case, ceramic having a good void ratio may be used to further decrease the thermal conductivity, or tempered glass having excellent impact resistance or quartz glass having excellent heat insulation and thermal resistance may be used.

During the vapor deposition process, the heat transferred from the heater 20 may cause expansion of the crucible 10 and the heater frame 30. Particularly, the housing 50 is exposed to the outside and thus the heat dissipates therefrom, the heat transfer to the housing 50 may be blocked by the insulating plate 40, or the housing 50 may be cooled by a cooling member, the thermal expansion amount of the crucible 10 and the heater frame 30 is comparatively higher than that of the housing 50. As described, when the thermal expansion amount of the crucible 10 and the heater frame 30 is different from that of the heater frame 30 and the housing 50, a large thermal stress is generated at a portion where each part contacts the supports 61 and 62, and accordingly, each part may be permanently deformed.

Thus, in the present exemplary embodiment, the deformation due to the difference of the thermal expansion amount can be suppressed by improving the shape of the center support 61 at the center of the crucible 10, the heater frame 30, and the housing 50 and the edge support 62 at the edge thereof.

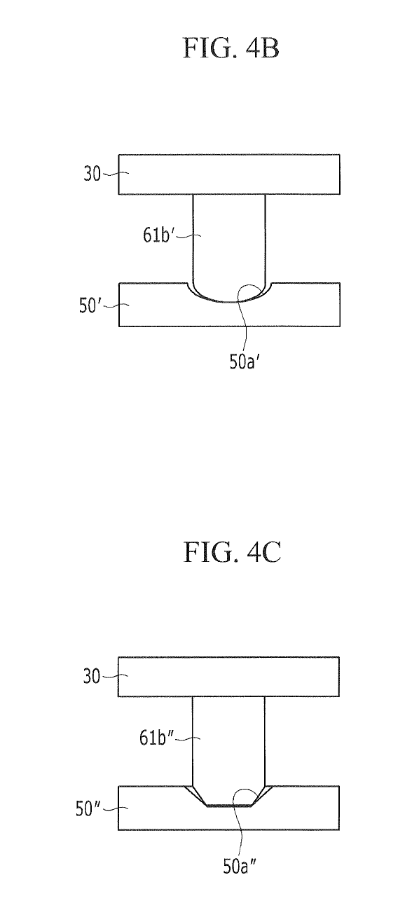

FIGS. 4A to 4C are schematic cross-sectional views of second center supports of the organic material evaporation source according to the exemplary embodiment of the present invention and exemplary variations thereof, and a detailed shape of the center support 61 will be described with reference to the drawings. The shape of first center support 61a is the same as that of the second center support 61b, and therefore, the shape of the center support 61 will be described, focusing the second center support 61b.

Referring to FIG. 4A, a groove (a second groove) 50a is formed at the housing 50 that contacts the second center support 61b such that a first end of the second center support 61b is inserted to the groove 50a of the housing 50 and a second end thereof contacts the heater frame 30. As described, the second center support 61b is disposed between the heater frame 30 and the housing 50, and movement to the horizontal direction in FIG. 4A is suppressed by inserting the first end of the second center support 61b to the groove 50a formed in the housing 50. Thus, the second center support 61b and the center of the heater frame 30 and the housing 50, supported by the second center support 61b cannot be changed, and accordingly, a constant distance can be maintained between the heater frame 30 and the housing 50.

Meanwhile, in the present exemplary embodiment, a cross-section of the first end of the second center support 61b, inserted to the groove 50a formed in the housing 50 has a rectangular shape. However, the cross-sectional shape of the first end of the second center support 61b can be variously modified.

Referring to FIG. 4B, a second center support 61b′ according to an exemplary variation of the present invention is disposed between a heater frame 30 and a housing 50′, and a first end of the second center support 61b′ is inserted to a groove 50a′ formed in the housing 50′. In the present exemplary variation, a cross-sectional shape of the first end of the second center support 61b′ has an edge that is not rectangular but round so that it is formed as a part of a circle or oval. In this case, a cross-sectional of the groove 50a′ formed in the housing 50′ is formed as a part of a circle or oval according to the shape of the first end of the second center support 61b′.

Referring to FIG. 4C, a second center support 61b″ according to another exemplary variation of the present invention is disposed between a heater frame 30 and a housing 50″, and a first end of the second center support 61b″ is inserted to a groove 50a″ formed in the housing 50″. In the present exemplary variation, the edges of the first end of the second center support 61b″ has a trapezoid shape having inclination rather than having a rectangular or round shape. In this case, the cross-section of the groove 50a″ formed in the housing 50″ is formed in a trapezoid shape according to the shape of the first end of the second center support 61b″.

In the exemplary embodiment of the present invention and the exemplary variations, the grooves 50a, 50a′, and 50a″ to which the first ends of the second center supports 61b, 61b′, and 61b″ are inserted are formed in the housings 50, 50′, and 50″, but they may be formed in the heater frames 30. Alternatively, the grooves may be formed both at the housings 50, 50′, and 50″ and the heater frames 30 and both ends of the second center supports 61b, 61b′, and 61b″ may be inserted thereto. According to the exemplary variations, the centers of the heater frames 30 and the housings 50, 50′, and 50″, supported by the second center supports 61b, 61b′, and 61b″ are not changed, constant distances between the heater frames 30 and the housings 50, 50′, and 50″ can be maintained.

In addition, as described above, the first center support 61a also may be formed to be the same as the second center supports 61b, 61W, and 61b″. That is, the first center support 61a is disposed between the crucible 10 and the heater frame 30, and a groove (a first groove) is formed at least one of the crucible 10 and the heater frame 30 to insert a first end or both ends of the first center support 61a thereto such that the crucible 10 and the heater frame 30 can be fixed. Accordingly, the center of the crucible 10 and the heater frame 30 cannot be changed, and a constant distance can be maintained between the crucible 10 and the heater frame 30.

As described, the heat emitted from the heater 20 is uniformly transferred to the crucible 10 so that temperature deviation of the crucible 10 can be suppressed by constantly maintaining the distance between the heater frame 30 and the housings 50, 50′, and 50″ and the distance between the crucible 10 and the heater frame 30, and the evaporated or sublimated organic material can be sprayed to a constant direction through the nozzle 11 of the crucible 10.

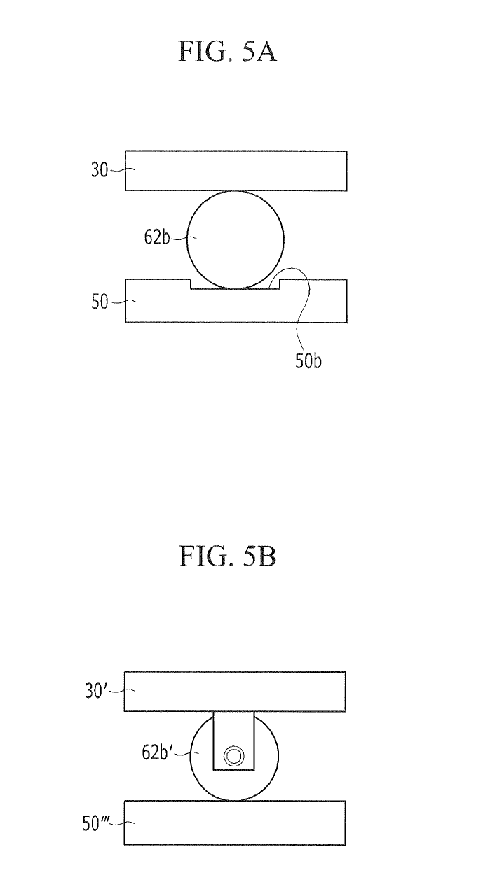

FIGS. 5A and 5B are schematic cross-sectional views of the second edge supports according to the exemplary embodiment of the present invention and exemplary variations, and a detailed description of the edge support 62 will be described with reference to the drawings. The shape of the first edge support 62a is the same as that of the second edge support 62a, and therefore the shape of the edge support 62 will be described, focusing the second edge support 62b.

Referring to FIG. 5A, a groove 50b is formed in the housing 50 that contacts the second edge support 62b according to the present exemplary embodiment, and thus a first end of the second edge support 62b is inserted to the groove 50b of the housing 50 and a second end of the second edge support 62b contacts the heater frame 30. As described, the second edge support 62b is disposed between the heater frame 30 and the housing 50.

Meanwhile, the second edge support 62b is formed in a sphere or cylinder shape to function as a ball or roller so that the second edge support 62b can horizontally move between the heater frame 30 and the housing 50. As described, since the second edge support 62b can horizontally move between the heater frame 30 and the housing 50, the thermal stress at a portion where the second edge support 62b and the heater frame 30 or the housing 50 can be minimized even though the thermal expansion amount of the heater frame 30 is different from that of the housing 50. Thus, the permanent deformation of the heater frame 30 and the housing 50 can be suppressed, and scratches on the heater frame 30 or the housing 50 due to the second edge support can be suppressed.

In this case, the groove 50b formed in the housing that contacts the second edge support 62b prevents the second edge support 62b from being deviated from a position for support the heater frame 30 and the housing 50 while moving. Meanwhile, in the present exemplary embodiment, the groove 50b is exemplarily formed in the housing 50 to prevent the second edge support 62b from being deviated from the original position, but the groove may be formed in the heater frame 30 or may be formed at both of the heater frame 30 and the housing 50.

Referring to FIG. 5B, a second edge support 62b′ according to an exemplary variation of the present exemplary embodiment, a second edge support 62b′ is fixed with a heater frame 30′. In further detail, the second edge support 62b′ is formed in a sphere or cylinder shape so that it can move between the heater frame 30′ and a housing 50″, and the rotation center of the second edge support 62b′ is connected to the heater frame 30′ and fixed thereto.

As described, in the present exemplary variation, the rotation center of the second edge support 62b′ is fixed to the heater frame 30′ to prevent deviation of the second edge support 62b′ from a position for supporting the heater frame 30′ and the housing 50′ while moving, suppress deformation due to the thermal expansion amount difference between the heater frame 30′ and the housing 50″, and suppress the heater frame 30′ and the housing 50″ from being scratched. Meanwhile, in the present exemplary variation, the rotation center of the second edge support 62b′ is exemplarily fixed to the heater frame 30′, but the rotation center of the second edge support 62b′ may be fixed to the housing 50″.

As described above, the first edge support 62a may be formed to be the same as the second edge supports 62b and 62b′. That is, the first edge support 62a is formed in a sphere or cylinder shape and movably arranged between the crucible 10 and the heater frames 30 and 30′. A groove is formed at least one of the crucible 10 and the heater frame 30 or the first edge support 62a is fixed to at least one of the crucible 10 and the heater frame 30 so that deviation due to movement can be suppressed.

Referring back to FIGS. 1 to 3, the organic material evaporation source 100 according to the present exemplary embodiment may further include the insulating plate 40 disposed between the heater frame 30 and the housing 50. As shown in FIG. 2, the insulating plate 40 is formed to surround the heater frame 30, and thus it functions to reflect the heat emitted from the heater 20 and the crucible 10 back to the direction of the crucible 10 and simultaneously prevent emission of the heat to the outside of the organic material evaporation source 100. Further, the insulating plate 40 functions to prevent the heat emitted from the heater 20 and the crucible 10 during the vapor deposition process from being transferred to the substrate.

According to the present exemplary embodiment, the housing 50 may include a cooling member. In further detail, the housing 50 has a double-wall structure divided into an inner wall and an exterior wall, and thus a space for taking in and emitting out a coolant can be formed between the walls. This is because to prevent emission of the heat generated from the heater 20 and the like to the outside, and a space where the coolant can directly flow may be formed in the housing 50 as described above or an additional cooling device may be formed in the outside of the housing 50.

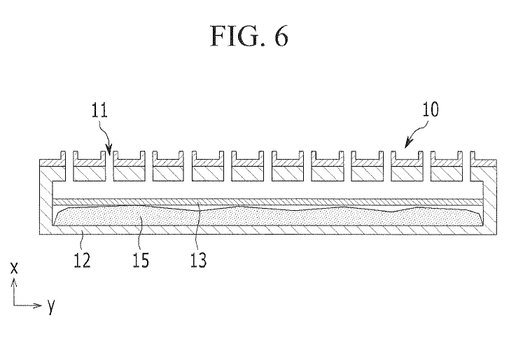

FIG. 6 is a cross-sectional view of the crucible of the organic material evaporation source according to the exemplary embodiment of the present invention of FIG. 3, taken along the line VI-VI. Hereinafter, arrangement of the nozzle 11 of the crucible 10 according to the present exemplary embodiment will be described with reference to the drawing.

With the above-stated configuration of the organic material evaporation source 100, the internal temperature deviation of the crucible 10 is minimized and accordingly, the organic material at each position in the crucible 10 can be uniformly exhausted. However, in this case that the nozzles are arranged in one side of the crucible with an inconsistent distance therebetween, vapor pressure of the evaporated or sublimated organic material is low in a portion where the distance between the nozzles is relatively narrow and high in a portion where the distance between the nozzles is relative wide. As described, when the vapor pressure deviation occurs according to the internal location of the crucible the evaporation temperature or sublimation temperature of the organic material is increased in the portion where then vapor temperature is relatively high, and accordingly the organic material may be differentially exhausted or degenerated.

Thus, the nozzles 11 of the crucible 10 according to the present exemplary embodiment is formed with a constant distance therebetween along one side of the crucible 10 to be communicated with the opening formed at one side of the body 12 of the crucible 10 to thereby constantly maintain the vapor pressure in the crucible 10.

However, when the nozzles 11 are arranged with the equivalent distance, the film thickness may not be uniform during the process for forming the organic thin film on the substrate. That is, a relatively large amount of organic materials is sprayed to a center portion of the substrate, corresponding to a center portion of the organic material evaporation source 100 so that the organic thin film becomes thick, and organic thin film formed at the edge of the substrate may be relatively thin.

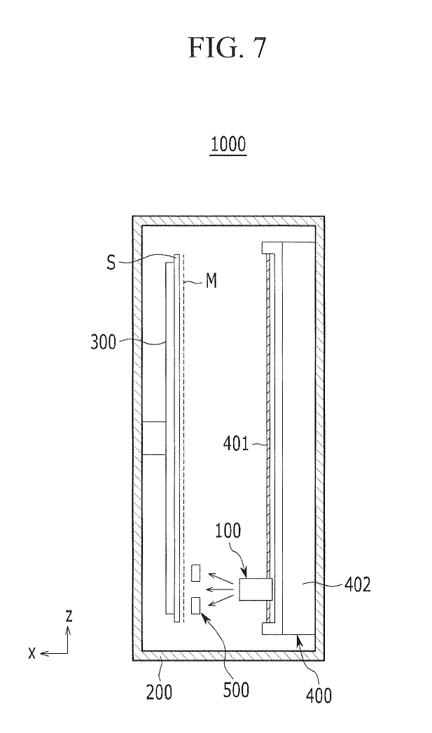

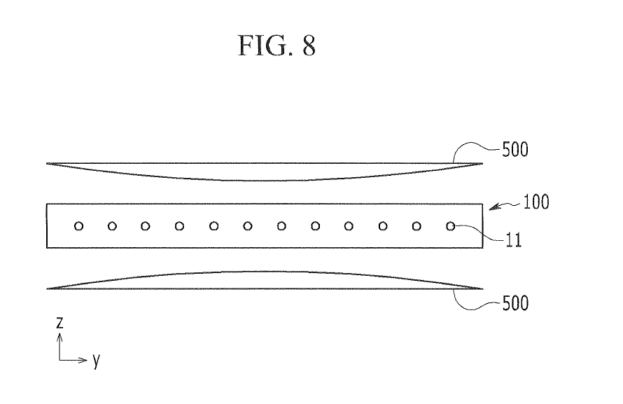

In the present exemplary embodiment, in order to compensate the thickness deviation in the organic thin film, a blocking plate is disposed between the substrate and the organic material evaporation source 100 in the vapor deposition apparatus, and this will be described with reference to FIGS. 7 and 8.

FIG. 7 is a schematic cross-sectional view of a vapor deposition apparatus according to an exemplary embodiment of the present invention. Referring to FIG. 7, a vapor deposition apparatus 1000 according to the present exemplary embodiment includes an organic material evaporation source 100, a chamber 200, a fixing member 300 to fix a substrate S, and an evaporation source supporting member 400 that supports the organic material evaporation source 100.

The organic material evaporation source 100 stores an organic material, heats the organic material for evaporation and sublimation, and then sprays the evaporated or sublimated organic material on the substrate S. A detailed configuration of the organic material evaporation source 100 is the same as the above description, and thus no further description will be provided.

The chamber 200 receives the organic material evaporation source 100, the substrate S, the substrate fixing member 300, and the evaporation source supporting member 400 to provide a space for vapor deposition. In order to maintain a vacuum state during the vapor deposition process, a vacuum pump (not shown) may be connected to the chamber 200.

The substrate fixing member 300 fixes the substrate S in the chamber 200. In the present exemplary embodiment, the substrate S is fixed to the ground along a direction (z-axis direction) that is approximately perpendicular to the ground in order to prevent the substrate S from being sagged, but the present invention is not limited thereto. On a front side of the substrate S fixed to the substrate fixing member 300, that is, a side that faces the organic material evaporation source 100, a mask M for determining a pattern of the organic thin film deposited thereon may be provided.

The evaporation source supporting member 400 supports the organic material evaporation source 100 in the chamber 200. The evaporation source supporting member 400 includes a support 402 that substantially supports the organic material evaporation source 100 and a guide 401 that can transfer the organic evaporation source 100 on the support 402. While being transferred by the guide 401, the organic material evaporation source 100 deposits the organic material on the substrate S. In the present exemplary embodiment, the substrate S is fixed along a direction (z-axis direction) that is approximately perpendicular to the ground, and therefore the organic material evaporation source 100 is transferred along the direction (z-axis) direction that is approximately perpendicular to the ground.

Referring to FIG. 7, a blocking plate 500 is disposed between the organic material evaporation source 100 and the substrate S. As described above, nozzles are arranged with an equivalent distance in order to maintain uniform vapor pressure in the crucible of the organic material evaporation source 100 such that the thickness of the deposited organic thin film may be not uniform. In the present invention, the non-uniformity of thickness of the organic thin film is compensated using the blocking plate 500.

FIG. 8 is a schematic front view of the organic material evaporation source, viewed from a location of the substrate in the vapor deposition apparatus according to the exemplary embodiment of the present invention. Referring to FIG. 8, the blocking plate 500 is arranged along a direction that is parallel with a direction (y-axis direction) in which the nozzles 11 of the organic material evaporation source 100 are arranged in a line with a constant distance with each other.

The blocking plate 500 is provided at upper and lower portions of the organic material evaporation source 100 with reference to the z-axis. In addition, the width of a center portion of each blocking plate 500 corresponding to the center portion of the organic material evaporation source 100 is relatively larger than that of the edge portion thereof to compensate a relatively large amount of organic material from being sprayed to the center portion of the substrate, corresponding to the center portion of the organic material evaporation source 100.

In the present exemplary embodiment, a pair of blocking plates 500 is symmetrically arranged, centering the organic material evaporation source 100, but the present invention is not limited thereto. Only one blocking plate may be formed along one side of the organic material evaporation source 100. However, when using only one blocking plate, the width of the center portion of the blocking plate should more increased in order to uniformly compensate the thickness of the organic thin film.

As described, in the present exemplary embodiment, the blocking plate 500 is disposed between the organic material evaporation source 100 and the substrate S to maintain a uniform thickness of the organic thin film formed on the substrate S. Meanwhile, a detailed shape of the blocking plate 500 for compensating the thickness of the organic thin film is not limited to the drawing, and may be variously modified to compensate a relatively large amount of organic materials sprayed to the center portion of the substrate S.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic material evaporation source comprising:
a crucible including a body and nozzle connected to an opening formed at one side of the body, the crucible being formed of a metal coated with steel use stainless (SUS);
a heater disposed adjacent to the crucible; and
a housing receiving the crucible and the heater.

2. The organic material evaporation source of claim 1, wherein the metal is copper or aluminum.

3. The organic material evaporation source of claim 1, wherein the thickness of the SUS formed on the metal is about 0.05 mm to about 0.5 mm.

4. The organic material evaporation source of claim 1, further comprising:
a heater frame disposed between the crucible and the housing, and supporting the heater, and
a support supporting the crucible and the heater frame, wherein the support comprises a first support that connects the crucible to the heater frame and a second support that connects the heater frame to the housing.

5. The organic material evaporation source of claim 4, wherein the first support comprises:
a first center support connected to a center portion of the crucible and the heater frame; and
a first edge support connected to an edge of the crucible and the heater frame, the first center support being formed to be fixed to the crucible and the heater frame, the first edge support being formed to be movable between the crucible and the heater frame.

6. The organic material evaporation source of claim 5, wherein the second support comprises:
a second center support connected to a center portion of the heater frame and the housing; and
a second edge support connected to an edge of the heater frame and the housing, the second center support being formed to be fixed to the heater frame and the housing, the second edge support being formed to be movable between the heater frame and the housing.

7. The organic material evaporation source of claim 6, wherein a first groove is formed in at least one of the crucible and the heater frame, connected with the first center support and a first end of the first center support is inserted to the first groove, and
a second groove is formed in at least one of the heater frame and the housing, connected with the second center support and a first end of the second center support is inserted to the second groove.

8. The organic material evaporation source of claim 6, wherein the first edge support and the second edge support have a sphere or cylinder shape.

9. The organic material evaporation source of claim 4, wherein the support comprises ceramic or glass.

10. The organic material evaporation source of claim 4, further comprising an insulating plate formed between the heater frame and the housing.

11. The organic material evaporation source of claim 1, wherein the housing comprises a cooling member.

12. The organic material evaporation source of claim 1, wherein the nozzles are arranged with a constant distance from each other along one side of the crucible.

13. An organic material vapor deposition apparatus comprising:
a substrate fixing member for fixing a substrate;
an organic material evaporation source for depositing an organic material on the substrate;
an evaporation source support member for supporting the organic material evaporation source; and
a chamber receiving the substrate, the substrate fixing member, the organic material evaporation source, and the evaporation source support member,
wherein the organic material evaporation source comprises,
a crucible including a body and nozzles connected to an opening formed at one side of the body, the crucible being formed of a metal coated with steel use stainless (SUS);
a heater disposed adjacent to the crucible, and
a housing receiving the crucible and the heater.

14. The organic material vapor deposition apparatus of claim 13, wherein the metal is copper or aluminum.

15. The organic material vapor deposition apparatus of claim 14, wherein the nozzles are arranged with a constant distance from each other along a first direction at one side of the organic material evaporation source, facing the substrate of the crucible.

16. The organic material vapor deposition apparatus of claim 15, further comprising a blocking plate disposed between the substrate and the organic material evaporation source.

17. The organic material vapor deposition apparatus of claim 16, wherein the blocking plate is extended along the first direction, the blocking plate disposed adjacent to one side of the organic material evaporation source when viewed from the substrate to the organic material evaporation source, and a width of the blocking plate, measured along a second direction that is perpendicular to the first direction, has a portion corresponding to the center of the organic material evaporation source formed to be greater than a portion corresponding to an edge of the organic material evaporation source.

18. The organic material vapor deposition apparatus of claim 17, wherein the blocking plate is formed as a pair that are symmetric with reference to the organic material deposition source.

19. The organic material vapor deposition apparatus of claim 16, wherein the evaporation support member comprises a guide for transferring the organic material evaporation source along a second direction that crosses the first direction, and the blocking plate is transferred with a speed that is the same as the transfer speed of the organic material evaporation source.
